(19) United States
(12) Patent Application Publication
(10) Pub. No.: US 2024/0194821 A1
(43) Pub. Date: Jun. 13, 2024

(54) LIGHT EMITTING ELEMENT

(71) Applicant: TOYODA GOSEI CO., LTD., Kiyosu-shi (JP)

(72) Inventor: Koji OKUNO, Kiyosu-shi (JP)

(21) Appl. No.: 18/529,851

(22) Filed: Dec. 5, 2023

(30) Foreign Application Priority Data
Dec. 9, 2022 (JP) 2022-197285

(51) Int. Cl. H01L 33/00; H01L 33/06; H01L 33/08; H01L 33/32

(52) U.S. Cl. CPC H01L 33/0008; H01L 33/06; H01L 33/08; H01L 33/325

(57) ABSTRACT

A light emitting element made of a face-up type group III nitride semiconductor, includes: a substrate; an n-layer made of an n-type group III nitride semiconductor; a first active layer using an EU-doped group III nitride semiconductor as a light emitting material and emitting red light; a first intermediate layer formed by stacking a first undoped layer made of a group III nitride semiconductor containing an undoped In and a first n-type layer made of a group III nitride semiconductor containing an n-type In in order; and a second active layer using a group III nitride semiconductor containing In as a light emitting material and emitting light with a wavelength shorter than that of the first active layer, wherein, in the first intermediate layer, an In composition is set so that a band gap does not absorb the light emitted from the first active layer.

### CROSS-REFERENCE RELATED APPLICATIONS

This application is based on and claims priority under 35 USC 119 from Japanese Patent Application No. 2022-197285 filed on Dec. 9, 2022.

### TECHNICAL FIELD

The present invention relates to a light emitting element.

### BACKGROUND ART

In recent years, there has been a demand for higher definition displays, and micro LED displays, in which each pixel is a minute LED on the order of 1 to 100 μm, are attracting attention. Various methods for achieving full color are known; for example, a method is known in which three active layers emitting blue, green, and red light are stacked in order on the same substrate.

In case of achieving red light emission by using an InGaN-based material, In composition (a molar ratio of In to the total group III metal in the group III nitride semiconductor) needs to be 40% or more, which makes it difficult to produce high-quality crystals. Therefore, as in JP-A-2014-175482, the use of Eu-doped GaN for red light emission is being considered. This red light emission is due to the transition in the 4f shell of Eu³⁺ ions.

However, in the method in which the three active layers emitting each color of blue, green, and red in order on the same substrate, the element configuration for the red light emission to be EU-doped GaN is not fully considered.

### SUMMARY OF INVENTION

In view of such a background, the invention is to provide a light emitting element including a first active layer of red light emission and a second active layer with a light emission wavelength shorter than that of the first active layer, with improved light emission efficiency of the first active layer.

An aspect of the present invention provides a light emitting element made of a face-up type group III nitride semiconductor, including: a substrate; an n-layer provided on the substrate and made of an n-type group III nitride semiconductor; a first active layer provided on the n-layer, using an EU-doped group III nitride semiconductor as a light emitting material, and emitting red light; a first intermediate layer provided on the first active layer and formed by stacking a first undoped layer made of a group III nitride semiconductor containing an undoped In and a first n-type layer made of a group III nitride semiconductor containing an n-type In in order: and a second active layer provided on the first intermediate layer, using a group III nitride semiconductor containing In as a light emitting material, and emitting light with a wavelength shorter than that of the first active layer, wherein, in the first intermediate layer, an In composition is set so that a band gap does not absorb the light emitted from the first active layer.

Another aspect of the present invention provides a light emitting element made of a face-up type group III nitride semiconductor, including: a substrate; an n-layer provided on the substrate and made of an n-type group III nitride semiconductor; a first active layer provided on the n-layer, using an EU-doped group III nitride semiconductor as a light emitting material, and emitting red light; a first intermediate layer provided on the first active layer, made of a group III nitride semiconductor containing In, and having a structure formed by stacking a p-type first p-type layer, a p-type first p⁺-layer, an n-type first n⁺-layer, and an n-type first n-layer in order from the first active layer; and a second active layer provided on the first intermediate layer, using a group III nitride semiconductor containing In as a light emitting material, and emitting light with a wavelength shorter than that of the first active layer, wherein the p-type impurity concentration of the first p⁺-layer is higher than the p-type impurity concentration of the first p-layer, and the n-type impurity concentration of the first n⁺-layer is higher than the n-type impurity concentration of the first n-layer, and the first p⁺-layer and the first n⁺-layer form a tunnel joint structure, and wherein, in the first intermediate layer, an In composition is set so that a band gap does not absorb the light emitted from the first active layer.

According to the above aspect of the present invention, in a light emitting element having a first active layer of red light emission and a second active layer that has a light emission wavelength shorter than that of the first active layer, a light emission efficiency of the first active layer can be improved.

### BRIEF DESCRIPTION OF DRAWINGS

FIG. 1 is a diagram illustrating a configuration of a light emitting element in a first embodiment and is a cross-sectional view perpendicular to a main surface of a substrate;

FIG. 2 is a diagram illustrating an equivalent circuit of the light emitting element in the first embodiment;

FIG. 3 is a diagram illustrating processes of manufacturing the light emitting element in the first embodiment;

FIG. 4 is a diagram illustrating processes of manufacturing the light emitting element in the first embodiment;

FIG. 5 is a diagram illustrating processes of manufacturing the light emitting element in the first embodiment;

FIG. 6 is a diagram illustrating processes of manufacturing the light emitting element in the first embodiment;

FIG. 7 is a diagram illustrating a configuration of a light emitting element in a modified example of the first embodiment and is a cross-sectional view perpendicular to the main surface of the substrate;

FIG. 8 is a diagram illustrating the configuration of the light emitting element in the modified example of the first embodiment and is a cross-sectional view perpendicular to the main surface of the substrate;

FIG. 9 is a diagram illustrating a configuration of a light emitting element in a second embodiment and is a cross-sectional view perpendicular to the main surface of the substrate; and

FIG. 10 is a diagram illustrating an equivalent circuit of the light emitting element in the second embodiment.

### DESCRIPTION OF EMBODIMENTS

A light emitting element made of a face-up type group III nitride semiconductor, includes: a substrate; an n-layer provided on the substrate and made of an n-type group III nitride semiconductor; a first active layer provided on the n-layer, using an EU-doped group III nitride semiconductor as a light emitting material, and emitting red light; a first intermediate layer provided on the first active layer and formed by stacking a first undoped layer made of a group Ill nitride semiconductor containing an undoped In and a first n-type layer made of a group III nitride semiconductor containing an n-type In in order; and a second active layer provided on the first intermediate layer, using a group III nitride semiconductor containing In as a light emitting material, and emitting light with a wavelength shorter than that of the first active layer In the first intermediate layer, an In composition is set so that a band gap does not absorb the light emitted from the first active layer.

A thickness of the first intermediate layer is 150 nm or less, and a thickness of the first undoped layer and a thickness of the first n-type layer are 10 nm or more.

A second intermediate layer provided on the second active layer and formed by stacking a second undoped layer made of the group III nitride semiconductor containing the undoped In and a second n-type layer made of the group III nitride semiconductor containing the n-type In in order; and a third active layer provided on the second intermediate layer, using a group III nitride semiconductor containing In as a light emitting material, and emitting with a wavelength shorter than that of the first active layer and different from that of the second active layer. One active layer of the second active layer and the third active layer is of blue light emission, and the other active layer is of green light emission. In the first intermediate layer and the second intermediate layer, the In composition is set so that the band gap does not absorb the light emitted from the first active layer and the second active layer. The green light emission of the second active layer and the third active layer corresponds to a structure in which a distortion relaxation layer which is a quantum well structure and a thickness of a well layer is adjusted so as not to emit light and a light emission layer which is a quantum well structure and emits light are stacked in order. A wavelength corresponding to band edge energy of the well layer of the distortion relaxation layer is set to be shorter than a light emission wavelength of the light emission layer.

Another light emitting element made of a face-up type group III nitride semiconductor, includes: a substrate; an n-layer provided on the substrate and made of an n-type group III nitride semiconductor; a first active layer provided on the n-layer, using an EU-doped group III nitride semiconductor as a light emitting material, and emitting red light; a first intermediate layer provided on the first active layer, made of a group III nitride semiconductor containing In, and having a structure formed by stacking a p-type first p-type layer, a p-type first p⁺-layer, an n-type first n⁺-layer, and an n-type first n-layer in order from the first active layer; and a second active layer provided on the first intermediate layer, using a group III nitride semiconductor containing In as a light emitting material, and emitting light with a wavelength shorter than that of the first active layer. The p-type impurity concentration of the first p⁺-layer is higher than the p-type impurity concentration of the first p-layer, and the n-type impurity concentration of the first n⁺-layer is higher than the n-type impurity concentration of the first n-layer, and the first p⁺-layer and the first n⁺-layer form a tunnel joint structure, and In the first intermediate layer, an In composition is set so that a band gap does not absorb the light emitted from the first active layer.

An In composition of the first p⁺-layer and the first n⁺-layer is higher than the In composition of the first p-layer and the first n-layer. The light emitting element according to claim 4, wherein the In composition of the first p⁺-layer is higher than the In composition of the first n⁺-layer.

A second intermediate layer provided on the second active layer and having a structure in which a p-type second p-layer, a p-type second p⁺-layer, an n-type second n⁺-layer, and an n-type second n-layer are stacked in order from the second active layer; and a third active layer provided on the second intermediate layer and using a group III nitride semiconductor containing In as a light emitting material and emitting light with a wavelength shorter than the first active layer and with a different wavelength from the second active layer. The p-type impurity concentration of the second p⁺-layer is higher than the p-type impurity concentration of the second p-layer, the n-type impurity concentration of the second n⁺-layer is higher than the n-type impurity concentration of the second n-layer, and the second p⁺-layer and the second n⁺-layer form a tunnel joint structure. In the first intermediate layer and the second intermediate layer, an In composition is set so that a band gap does not absorb the light emitted from the first active layer and the second active layer. One active layer of the second active layer and the third active layer is of blue light emission, and the other active layer is of green light emission, wherein the green light emission of the second active layer and the third active layer corresponds to a structure in which a distortion relaxation layer which is a quantum well structure and a thickness of a well layer is adjusted so as not to emit light and a light emission layer which is a quantum well structure and emits light are stacked in order, and wherein a wavelength corresponding to band edge energy of the well layer of the distortion relaxation layer is set to be shorter than a light emission wavelength of the light emission layer.

The wavelength corresponding to the band edge energy of the well layer of the distortion relaxation layer is set to be equal to the light emission wavelength of the blue light emission of the second active layer and the third active layer. A difference between the light emission wavelength of the light emission layer and the wavelength corresponding to the band edge energy of the well layer of the distortion relaxation layer is set to be in the range of 40 nm and more or 100 nm or less.

### First Embodiment

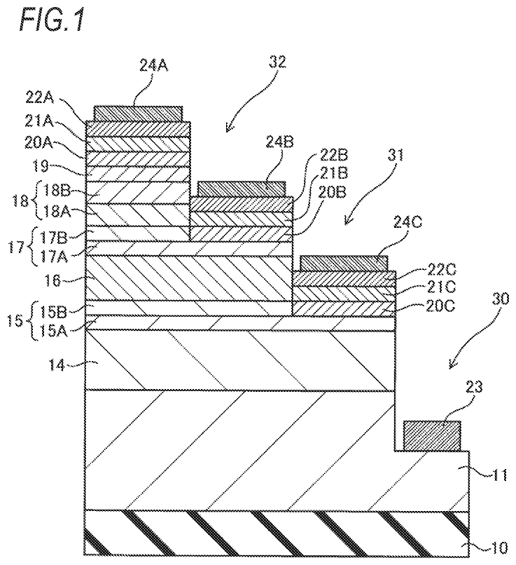

FIG. 1 is a diagram illustrating a configuration of a light emitting element in the first embodiment, and is a sectional view perpendicular to a main surface of the substrate. The light emitting element in the first embodiment can emit blue, green, and red light, respectively. Further, the light emitting element in the first embodiment is a face-up type that takes out light from an upper surface side (electrode side) of the substrate. The upper surface side electrode is generally made of a material that is transparent to the light emission wavelength. The material is, for example. ITO, IZO, or the like. It is noted that, in the first embodiment, one pixel has a structure of one chip, but a monolithic type may be used. In other words, a micro LED display element may be used in which the element structures of the light emitting elements in the first embodiment are included in a matrix on the same substrate.

### 1. Configuration of Light Emitting Element

As illustrated in FIG. 1, the light emitting element in the first embodiment includes a substrate 10, an n-layer 11, a first active layer 14, a first intermediate layer 15, a second active layer 16, and a second intermediate layer 17, a third active layer 18, a protective layer 19, re-growth layers 20A to 20C, electron blocking layers 21A to 21C, p layers 22A to 22C, an n-electrode 23, and p-electrodes 24A to 24C.

The substrate 10 is a growth substrate on which a group Ill nitride semiconductor is grown. For example, sapphire, Si, GaN, or the like is the substrate.

The n-layer 11 is an n-type semiconductor provided on the substrate 10 via a low-temperature buffer layer and a high-temperature buffer layer (not illustrated). However, the buffer layer may be provided as necessary, and the buffer layer may not be provided when the substrate is made of GaN. The n-layer 11 is made of, for example, n-GaN, n-AlGaN, or the like. The Si concentration is, for example, 1×10¹⁸ to 100×10¹⁸ cm⁻³.

The first active layer 14 is a light emission layer with an SQW or MQW structure provided on the n-layer 11. The light emission wavelength is red and the wavelength is 620 to 623 nm. The first active layer 14 has a structure in which 1 to 20 pairs of barrier layers made of AlGaN and well layers made of Eu-doped GaN are stacked alternately. Red light is emitted due to Eu ions of the Eu-doped GaN.

The amount of Eu doping in the well layer is preferably 1×10¹⁷ to 1×10²¹ cm 3. In this range, the red light can be efficiently emitted.

As described above, in the first embodiment, the Eu-doped GaN is used as the red light emitting material of the first active layer 14 instead of InGaN with a high In composition. For this reason, the light emission efficiency of the red light can be improved. The details are as follows.

In general, it is difficult to improve the crystal quality of InGaN with a high In composition, but the first embodiment is Eu-doped GaN and does not contain In, so that the crystal quality can be improved, and the light emission efficiency can be improved. Furthermore, Eu also functions as a surfactant and can be expected to improve crystal flatness.

In addition, the InGaN needs to be grown at low temperatures to prevent In from evaporating, which results in a decrease in crystal quality, but since Eu-doped GaN does not contain In, the growth temperature can be raised to improve the crystal quality, and the light emission efficiency can be improved.

In addition, in the case of the InGaN, a heterojunction is formed, and crystal defects are likely to occur due to the release of distortion, but since the Eu-doped GaN has a homojunction, or the difference in lattice constants can be made small, the crystal defects can be reduced, and the light emission efficiency can be improved.

Furthermore, in the case of the InGaN, the quantum confined stark effect (QCSE) occurs due to the distortion, and thus, the transition probability decreases, but in the Eu-doped GaN, there is no QCSE, and thus, the transition probability does not decrease, so that high light emission efficiency can be achieved. The above are the advantages of using the Eu-doped GaN as a red light emitting material.

It is noted that, in the first embodiment, Eu-doped GaN is used as the well layer of the first active layer 14, but the material is not limited to this, and any Eu-doped group III nitride semiconductor may be used. For example, Eu-doped InGaN or Eu-doped AlGaN can also be used. However, from the viewpoint of crystal quality and suppression of distortion in the element structure, it is preferable to use Eu-doped GaN similarly to the first embodiment.

The well layer of the first active layer 14 may be doped with impurities other than Eu. For example, the well layer may be doped with Si, O, Mg, or the like. The light emission efficiency can be improved.

A buffer layer may be provided between the well layer and the barrier layer to prevent Eu in the well layer from diffusing into the barrier layer. The buffer layer is, for example, undoped GaN.

Furthermore, the first active layer 14 is not limited to a quantum well structure, and may be an Eu-doped GaN single layer. When a thick single layer of Eu-doped GaN is used, the volume of Eu-doped GaN increases, and the rate at which injected carriers are combined increases. In addition, a structure in which undoped GaN and Eu-doped GaN are alternately and repeatedly stacked may be used. By alternately stacking layers, it is possible to suppress changes in crystal quality in the stacking direction due to Eu doping and form a uniform light emission layer.

Furthermore, in the related art, an underlying layer is provided between the n-layer 11 and the first active layer 14 to relax the crystal distortion of the first active layer 14, but in the first embodiment, since the first active layer is made of the Eu-doped GaN, and there is no difference or sufficiently small difference in lattice constant from that of the n-layer 11, there is no need to provide the underlying layer, and the first active layer can be provided directly on the n-layer 11. For this reason, it is possible to simplify the element structure and reduce costs.

Furthermore, an ESD layer may be provided between the n-layer 11 and the first active layer 14 to improve the electrostatic breakdown voltage. The ESD layer is, for example, undoped or lightly doped with Si, GaN, InGaN, or AlGaN.

The first intermediate layer 15 is a semiconductor layer provided on the first active layer 14 and is located between the first active layer 14 and the second active layer 16. The first intermediate layer 15 is a layer provided so that light emission from the first active layer 14 and light emission from the second active layer 16 can be individually controlled. It also has the role of protecting the first active layer 14 from etching damage when forming a second groove 31, which will be described later.

The first intermediate layer 15 has a structure in which an undoped layer 15A and an n-type layer 15B are stacked in order from the first active layer 14 side. By adopting such a two-layer structure, the distance between pn junctions can be adjusted, and each active layer can be controlled uniformly. The details will be described later.

The undoped layer 15A and the n-type layer 15B are made of the same material except for impurities. The material of the first intermediate layer 15 is a group III nitride semiconductor containing In, and for example, is preferably InGaN. The surfactant influence of In can reduce the roughness of the surface of the first intermediate layer 15 and improve the surface flatness. Furthermore, lattice distortion can be relaxed.

The In composition of the first intermediate layer 15 may be set so as to have a band gap that does not absorb light emitted from the first active layer 14. More preferably, the band gap is set so that the light emitted from the first active layer 14, the second active layer 16, and the third active layer 18 is not absorbed. The preferred In composition is 10% or less, more preferably 5% or less, and still more preferably 2% or less. When the In composition is greater than 10%, the surface of the first intermediate layer 15 may become rough In is freely set as long as it is greater than 0%, and may be at a doping level (a level that does not form a mixed crystal). For example, GaN has an In concentration of 1×10¹⁴ cm⁻³ or more and 1×10²² cm⁻³ or less.

The undoped layer 15A is undoped, and the n-type layer 15B is Si-doped. The Si concentration of the n-type layer 15B is preferably 1×10¹⁷ to 1×10²⁰ cm⁻³. The n-type layer 15B may be modulated and doped with Si, or there may be an undoped region in a partial area of the n-type layer 15B.

The thickness of the first intermediate layer 15 is preferably 20 to 150 nm. When it is thicker than 150 nm, the surface of the first intermediate layer 15 becomes rough. Moreover, when it is thinner than 20 nm, it may become difficult to control the depth of the second groove 31 in the first intermediate layer 15 when forming the second groove 31, which will be described later. The thickness is more preferably 30 to 100 om, still more preferably 50 to 80 nm.

Furthermore, the thickness of the undoped layer 15A is preferably 10 nm or more. This is for controlling the etching depth and avoiding etching damage to the first active layer 14. Further, the thickness of the n-type layer 15B is preferably 10 nm or more. This is to independently control the light emitting characteristics of each active layer.

The second active layer 16 is a light emission layer with an SQW or MQW structure provided on the first intermediate layer 15. The light emission wavelength is blue and ranges from 430 to 480 nm. The first active layer 14 has a structure in which one to seven pairs of barrier layers made of AlGaN and well layers made of InGaN are alternately stacked. Blue light is emitted due to band edge emission of InGaN. More preferably 1 to 5 pairs, still more preferably 1 to 3 pairs.

The second intermediate layer 17 is a semiconductor layer provided on the second active layer 16 and is located between the second active layer 16 and the third active layer 18.

The second intermediate layer 17 is provided for the same reason as the first intermediate layer 15, and is a layer provided to enable separate control of light emission from the second active layer 16 and light emission from the third active layer 18. It also has the role of protecting the second active layer 16 from etching damage when forming a third groove 32, which will be described later.

The second intermediate layer 17 has a structure in which an undoped layer 17A and an n-type layer 17B are stacked in order from the second active layer 16 side. The reason for having such a two-layer structure is the same as that for the first intermediate layer 15, and the details will be described later. The undoped layer 17A and the n-type layer 17B have the same material and structure as the undoped layer 15A and the n-type layer 15B. The In composition of the second intermediate layer 17 may be set so as to have a band gap that does not absorb light emitted from the first active layer 14 and the second active layer 16. More preferably, the band gap is set so that the light emitted from the first active layer 14, the second active layer 16, and the third active layer 18 are not absorbed. The undoped layer 17A and the n-type layer 17B are made of the same material except for impurities. The first intermediate layer 15 and the second intermediate layer 17 may be made of the same material.

The undoped layer 17A is undoped, and the n-type layer 17B is doped with Si Itis preferable that the second intermediate layer 17 is thinner than the first intermediate layer 15 and that the In composition of the second intermediate layer 17 is also higher than the In composition of the first intermediate layer 15. This is because the third active layer 18 of the green light emission is more susceptible to beat damage than the second active layer 16 of the blue light emission, and the influence of distortion at the interface is greater.

The third active layer 18 is a layer provided on the second intermediate layer 17, and has a structure in which a distortion relaxation layer 18A and an SQW or MQW quantum well structure layer (light emission layer) 18B are stacked in order.

The distortion relaxation layer 18A has an SQW structure in which a barrier layer and a well layer are stacked in order and is a quantum well structure in which the thickness of the well layer is adjusted to be thin so as not to emit light. For example, by setting the thickness of the well layer to 1 nm or less, it is possible to prevent the well layer from emitting light. The barrier layer is AlGaN, and the well layer is InGaN. The wavelength corresponding to the band edge energy of the well layer of the distortion relaxation layer 18A may be shorter than the light emission wavelength of the quantum well structure layer 18B, for example, when the light emission wavelength of the quantum well structure layer 18B is 500 to 560 nm, the wavelength is 400 to 460 nm. Preferably, the wavelength is 40 to 100 nm shorter than the light emission wavelength of the quantum well structure layer 18B.

The wavelength corresponding to the band edge energy of the well layer of the distortion relaxation layer 18A may be equal to the light emission wavelength of the second active layer 16.

The band edge energy in the well layer of the distortion relaxation layer 18A can be controlled by the thickness of the well layer. That is, by making the thickness of the well layer of the distortion relaxation layer 18A sufficiently thin, energy of a subband in the well increases, and the band edge energy increases. Accordingly, the light emission wavelength may be made shorter than the light emission wavelength of the quantum well structure layer 18B. Furthermore, when the thickness of the well layer of the distortion relaxation layer 18A is made thinner, the subband further increases, and the energy difference with the barrier layer will become smaller. That is, it becomes close to the band edge energy of the barrier layer. As a result, it becomes difficult for carriers to be confined in the well layer of the distortion relaxation layer 18A. making it difficult to emit light, so that it functions as a portion of the barrier layer of the quantum well structure layer 18B and also achieves a distortion relaxation influence at the same time.

In this way, by forming the distortion relaxation layer 18A having a well layer with worse carrier confinement than the well layer of the quantum well structure layer 18B, it is possible to form the distortion relaxation layer 18A that does not emit light.

In short, the material and layer configuration of the distortion relaxation layer 18A may be set so that the effective lattice constant of the entire distortion relaxation layer 18A is between the lattice constant of the second intermediate layer 17 and the lattice constant of the quantum well structure layer 15B, and the thickness of the well layer may be set so that the distortion relaxation layer 18A does not emit light.

Although the distortion relaxation layer 18A may have an MQW structure in which two or more pairs of barrier layers and well layers are stacked, since the third active layer 18 becomes thick, it is preferable to have an SQW structure. In addition, a plurality of distortion relaxation layers 18A may be provided to relax distortion in stages.

By providing the distortion relaxation layer 18A as described above, the distortion of the quantum well structure layer 18B stacked on the distortion relaxation layer 18A can be relaxed, and the crystal quality of the well layer of the quantum well structure layer 18B can be improved.

The quantum well structure layer 18B is a light emission layer with an SQW or MQW structure provided on the distortion relaxation layer 18A The light emission wavelength is green and ranges from 510 to 570 nm. The quantum well structure layer 18B has a structure in which one to seven pairs of barrier layers made of GaN and well layers made of InGaN are alternately stacked. Green light is emitted due to band edge emission of InGaN. The number of pairs is more preferably 1 to 5 pairs, still more preferably 1 to 3 pairs. Further, it is preferably equal to or less than the number of pairs in the second active layer 16, and still more preferably less.

It is preferable to set the ratio of the thickness of the second active layer 16 to the thickness of the third active layer 18 to be 30% or less. Distortion in the quantum well structure layer 18B can be more effectively relaxed, and the distance between p-n junctions becomes constant under each of the p-electrodes 24A to 24C, making device characteristics uniform under each of the p-electrodes 24A to 24C.

The protective layer 19 is a semiconductor layer provided on the third active layer 18. The protective layer 19 is a layer that protects the active layer and also functions as an electron blocking layer. The protective layer 19 may be made of a material having a wider band gap than the well layer of the third active layer 18, such as AlGaN, GaN, and InGaN. The thickness of the protective layer 19 is preferably 2.5 to 50 nm, more preferably 5 to 25 nm. The protective layer 19 may be doped with impurities, or may be doped with Mg. In that case, the Mg concentration is preferably 1×10¹² to 1000×10¹⁵ cm⁻³.

A partial area of the protective layer 19 is etched to provide grooves, and the third groove 32 that reaches the undoped layer 17A of the second intermediate layer 17 from the protective layer 19, and a second groove 31 that reaches the undoped layer 15A of the first intermediate layer 15, and a first groove 30 that reaches the n-layer 11 are provided.

In this way, by making the third groove 32 deep enough to reach the undoped layer 17A and removing the n-type layer 17B of the second intermediate layer 17 below a p-electrode 24B, no n-type layer is located on the second active layer 16, so that the second active layer 16 is allowed to emit light. Further, the second groove 31 is made deep enough to reach the undoped layer 15A of the first intermediate layer 15 for the same reason, and by removing the n-type layer 15B of the first intermediate layer 15 below the p-electrode 24C, no n-type layer is located on the first active layer 14, so that the first active layer 14 is allowed to emit light.

The re-growth layers 20A to 20C are provided on the protective layer 19, on the second intermediate layer 17 exposed on the third groove 32 bottom surface, and on the first intermediate layer 15 exposed to the second groove 31 bottom surface, respectively. The structure of the re-grown layers 20A to 20C is similar to that of the protective layer 19.

The electron blocking layers 21A to 21C are semiconductor layers provided on the re-growth layers 20A to 20C, respectively, and are blocking layers to efficiently confine electrons injected from the n layer 11 to the first active layer 14, the second active layer 16, and the third active layer 18. The electron blocking layer may be a single layer of GaN or AlGaN, or may have a structure in which two or more of AlGaN. GaN, and InGaN are stacked, or a structure in which these materials are stacked with only the composition ratio changed. In addition, it may have a superlattice structure. The thickness of the electron blocking layers 21A to 21C is preferably 5 to 50 nm, more preferably 5 to 25 nm. The Mg concentration of the electron blocking layers 21A to 21C is preferably 1×10¹⁹ to 100×10¹⁹ cm⁻³.

The p-layers 22A to 22C are semiconductor layers provided on the electron blocking layers 21A to 21C, respectively, and are configured with a first layer and a second layer in order from the electron blocking layer 21 side. The first layer is preferably p-GaN or p-InGaN. The thickness of the first layer is preferably 10 to 500 nm, more preferably 10 to 200 nm, still more preferably 10 to 100 nm. The Mg concentration in the first layer is preferably 1×10¹⁹ to 100×10¹⁹ cm⁻³. The second layer is preferably p-GaN or p-InGaN. The thickness of the second layer is preferably 2 to 50 nm, more preferably 4 to 20 nm, still more preferably 6 to 10 nm. The Mg concentration of the second layer is preferably 1×10²⁰ to 100×10²⁰ cm⁻³.

The n-electrode 23 is an electrode provided on the n-layer 11 exposed on the bottom surface of the first groove 30. When the substrate 10 is made of a conductive material, the n-electrode 23 may be provided on the back surface of the substrate 10 without providing the first groove 30. The material of the n-electrode 23 is, for example, Ti/Al or V/Al.

The p-electrodes 24A to 24C are electrodes provided on the p-layers 22A to 22C, respectively. The material of the p-electrodes 24A to 24C is, for example, Ag, Ni/Au, Co/Au, ITO, IZO, or the like. Since the light emitting element in the first embodiment is of a face-up type, a transparent electrode such as ITO or IZO is preferable.

### 2 Operation of Light Emitting Element

The operation of the light emitting element in the first embodiment will be described. In the light emitting element in the first embodiment, green light can be emitted from the third active layer 18 by applying a voltage between the p-electrode 24A and the n-electrode 23, blue light can be emitted from the second active layer 16 by applying a voltage between the p-electrode 24B and the n-electrode 23, and red light can be emitted from the first active layer 14 by applying a voltage between the p-electrode 24C and the n-electrode 23. Furthermore, two or more of blue, green, and red can be emitted at the same time. In this manner, the light emitting element in the first embodiment can control blue, green, and red light emission by selecting the electrode to which the voltage is applied, and can be used as one pixel of a display.

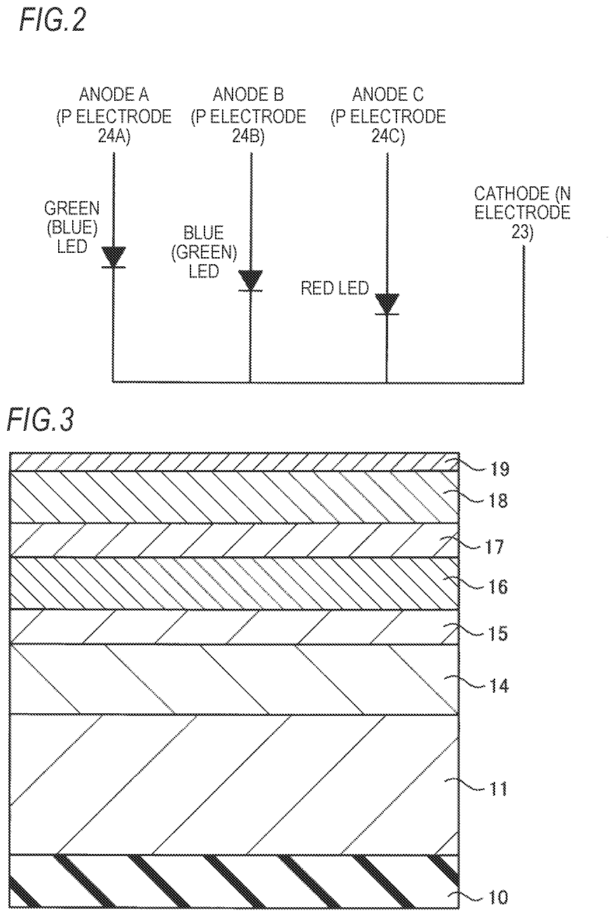

FIG. 2 illustrates an equivalent circuit of the light emitting element in the first embodiment. As illustrated in FIG. 2, the light emitting element according to the first embodiment has a structure in which red, blue, and green LEDs are formed in one element, and full-color light emission can be realized with one element. For this reason, it is possible to make the size of one element much smaller than separately preparing red, blue, and green LEDs and arranging these LEDs on the same substrate to create a one-pixel full-color light emitting element. Furthermore, with the structure of the first embodiment, the process of separately preparing and arranging red, blue, and green LEDs can be omitted, and thus, the manufacturing cost can be significantly reduced, resulting in a very low-cost full-color light emitting element and a light emitting display using the light emitting element can be realized.

Here, in the first embodiment, since the first intermediate layer 15 and the second intermediate layer 17 contain In, so that the surface flatness of the first intermediate layer 15 and the second intermediate layer 17 is improved by the In surfactant influence, and the surface flatness of the second active layer 16 and the third active layer 18 can also be improved. In addition, the lattice distortion caused by a lattice constant difference between the underlying layer 13 and the first active layer 14 can be relaxed. As a result, according to the light emitting element in the first embodiment, the light emission efficiency can be improved.

In addition, in the first embodiment, the first intermediate layer 15 and the second intermediate layer 17 have a two-layer structure of the undoped layer 15A, 17A and the n-type layer 15B, 17B, which is to adjust the pn joining distance.

Here, the pn joining distance is explained. The pn joining distance is equivalent to the film thickness that is empty during zero bias. In the LED, the pn joining distance the total thickness of the active layer of the active layer of undoped or low doped sandwiched between the p-layer with high concentration accelerator impurities and the n-layer with high concentration donor impurities.

When the first intermediate layer 15 and the second intermediate layer 17 are undoped layers, the pn joining distance (thickness of the empty layer) corresponds to a distance from the electron blocking layer 21A with highly doped with the acceptor impurities in the area under the p-electrode 24A to the n-layer 11 highly doped with the donor impurities, that is, the film thickness including the first active layer 14, the second active layer 16, the third active layer 18. the first intermediate layer 15, and the second intermediate layer 17. In addition, the pn joining distance corresponds to, under the p-electrode 24B, the distance from an electron blocking layer 21B to the n-layer 11, that is, the film thickness including a portion of the first active layer 14, the second active layer 16, the first intermediate layer 15, and the second intermediate layer 17. Further, the pn joining distance corresponds to, under the p-electrode 24C, the distance from the electron blocking layer 21C highly doped with the acceptor impurities to the n-layer 11, that is, the film thickness including a portion of the first active layer 14 and the first intermediate layer 15.

For this reason, in these three cases, the pn joining distances are different, and the driving voltage, the current injection efficiency, and the opposite direction current are different. Further, when the voltage is applied to the p-electrode 24A to allow the third active layer 18 to emit light, the carriers of the electrons and the holes are supplied to all the active layers, and the second active layer 16 and the first active layer 14 may emit light. Similarly, when the voltage is applied to the p-electrode 24B to allow the second active layer 16 to emit light, the first active layer 14 may also emit light.

In first embodiment, such problems are solved with the intermediate structure. In other words, in the first embodiment, the first intermediate layer 15 is configured with the two layers of the undoped layer 15A and the n-type layer 15B highly doped with the donor impurities, the second intermediate layer 17 is configured with the two layers of the undoped layer 17A and the n-type layer 17B highly doped with the donor impurities, and the n-type layers 15B and 17B doped with Si are used as n-type layers.

For this reason, the pn joining distance is a distance from the electron blocking layer 21A to the n-type layer 17B in the second intermediate layer 17 in the area under the p-electrode 24A, a distance from of the electron blocking layer 21B to the n-type layer 15B of the first intermediate layer 15 in the area under the p-electrode 24B, and a distance from the electron blocking layer 21C to the n-layer 11 in the area under the p-electrode 24C. That is, the pn joining distance under all electrodes correspond to the total thickness of the undoped layer among the one active layer and intermediate layer without a plurality of active layers.

Here, by properly controlling the thickness of the undoped layer 15A of the first intermediate layer 15, the thickness of the undoped layer 17A of the second intermediate layer 17, the thickness and the number of pairs of the distortion relaxation layer 18A, and the number of pairs of the second active layer 16 and the quantum well structural layer 18B, the pn joining distances can be allowed to be equal in these three cases. As a result, in these three cases, a variation in the driving voltage, the current injection efficiency, and the opposite direction current can be suppressed, and thus, uniform control can be obtained. Furthermore, in these three cases, only one of the first active layers 14, the second active layer 16, and the third active layer 18 is provided in the pn joint, and the n-type layer in the intermediate layer becomes a barrier layer for the holes, so that it is difficult for the holes to be injected into the lower active layer beyond the n-type layer of the intermediate layer. As a result, it is possible to suppress an active layer other than the active layer that desires to emit light at the pn joining from emitting light.

In addition, in order to adjust the pn joining distance, a layer such as n-GaN or undoped GaN may be inserted between the n-layer 11 and the first active layer 14.

In the first embodiment, the three active layers of red light emission, green light emission, and blue light emission are placed in order from the substrate 10, the first active layer 14 of the red light emission, the second active layer 16 of the blue light emission, and the third active layer 18 of the green light emission are placed in order.

It is the following reasons that the first active layer 14 of the red light emission is the closest to the substrate 10. First, the light emitting element in the first embodiment is of a face-up type, and since light is extracted from the upper surface of the substrate 10, when there is the first active layer 14 at the top of the second active layer 16 and the third active layer 18, blue light and green light from the second active layer 16 and the third active layer 18 are partially absorbed into the first active layer 14. To prevent such absorption from occurring, the first active layer 14 of the red light emission is placed on the substrate 10 side from the second active layer 16 and the third active layer 18.

Second, this is because of increasing the growth temperature of the first active layer 14 to improve the crystal quality. The red light emitting material of the first active layer 14 is EU-doped GaN, and does not include InGaN, so that the growth temperature can be increased to improve crystalline quality. Here, after the second active layer 16 and the third active layer 18 are formed first, and when the third active layer 18 is grown at a higher temperature than those growth temperature, the second active layer 16 and the third active layer 18 include InGaN, which causes heat damage. Therefore, by forming the first active layer 14 of the red light emission before the second active layer 16 and the third active layer 18, the growth temperature of the first active layer 14 is high, and the crystal quality is increased, which prevents heat damage to the active layer 16 and the third active layer 18.

It is the following reason that the second active layer 16 of the blue light emission is the second from the substrate 10 side. The second active layer 16 and the third active layer 18 use InGaN as light emitting material, but the second active layer 16 which is blue light emission has a lower In composition than the third active layer 18 which is green light emission. For this reason, the second active layer 16 can grow at a higher temperature than the third active layer 18 to improve the crystal quality. Here, after the third active layer 18 is formed first, and when the second active layer 16 is grown at a higher temperature than the growth temperature of the third active layer 18, the third active layer 18 will receive heat damage because the third active layer 18 includes the InGaN. Therefore, by forming the second active layer 16 of blue light emission ahead of the third active layer 18, the growth temperature of the second active layer 16 is increased, and the crystal quality is increased, and the heat damage to the third active layer 18 is prevented.

It is noted that, since there is the third active layer 18 at the top of the second active layer 16, the blue light from the second active layer 16 is partially absorbed into the third active layer 18. However, in general, since the blue light emission efficiency of the InGaN is sufficiently higher than the green light emission efficiency, even when such absorption is not a problem.

As described above, from the viewpoint of increasing the growth temperature and improving the crystal quality, similarly to the first embodiment, the order of the first active layer 14 of the red light emission, the second active layer 16 of the blue light emission, the third active layer 18 of the green light emission from the substrate 10 side is preferable. However, emphasis is on the viewpoint of preventing re-absorption of light by the active layers, and the order of the first active layer 14 of the red light emission, the third active layer 18 of the green light emission, and the second active layer 16 of the blue light emission from the substrate 10 side may be suitable.

### 3. Processes of Manufacturing Light Emitting Elements

Next, the processes of manufacturing the light emitting elements in first embodiment are explained with reference to the drawings.

First, the substrate 10 is prepared, hydrogen, nitrogen, and ammonia as needed are added, and heat treatment of the substrate is performed.

Next, a buffer layer is formed on the substrate 10, and the n-layer 11, the first active layer 14, the first intermediate layer 15, the second active layer 16, the second intermediate layer 17, the third active layer 18, the protective layer 19 formed on the buffer layer in order by an MOCVD method (refer to FIG. 3). Various raw gases in the MOCVD method are, for example, as follows. Ga raw gas is TMG (trimethyl gallium), TEG (triethyl galium), AL raw gas is TMA (trimethyl aluminum), and In raw gas is TMI (trimethyl Indium), SI raw material gas is sylan, Mg raw gas is Cp₂Mg (bis (cyclopentadienyl) magnesium), EU raw material gas is EuCpPm, (bis (normal propyltetramethylpentadenil) Europium), EU(DPM);, or the like.

The preferred growth temperature of each layer is as follows.

The growth temperature of the first active layer 14 is preferably 900 to 1100° C. Since the red light emitting material of the first active layer 14 is EU-doped GaN instead of InGaN of the In composition, the growth temperature can be increased in this way. As a result, the crystal quality can be improved, and the light emission efficiency can be improved. The growth temperature is more preferably 950 to 1050° C. The first active layer 14 is configured with a well layer and a barrier layer, but the well layer and the barrier layer may be formed at the same temperature, or the temperature may be different in the above temperature range. When the temperature is different, it is preferable to lower the growth temperature of the well layer than the growth temperature of the barrier layer.

The growth temperature of the first intermediate layer 15 is preferably 700 to 1000° C. This is to suppress heat damage to the first active layer 14. Further, when it is lower than 700° C., pits and dotted defects caused by penetrating dislocation will likely occur. The growth temperature is more preferably, 800 to 950° C., and still more preferably 850 to 950° C.

The growth temperature of the second active layer 16 is preferably 700 to 950° C. The crystal quality can be improved, and the light emission efficiency can be improved. The second active layer 16 is configured with the well layer and the barrier layer, but the well layer and the barrier layer may be formed at the same temperature, or the temperature may be different within the above temperature range. When the temperature is different, it is preferable to lower the growth temperature of the well layer than the growth temperature of the barrier layer. Further, the growth temperature of the second active layer 16 is preferably lower than the growth temperature of the first active layer 14.

The growth temperature of the second intermediate layer 17 is preferably the same as the growth temperature of the first intermediate layer 15. However, the growth temperature of the second intermediate layer 17 is preferably lower than the growth temperature of the first intermediate layer 15. The second active layer 16 of the blue light emission is red light emission and is more susceptible to heat damage than the first active layer 14, which is the EU-doped GaN, which increases the influences of distortion at the interface.

The growth temperature of the distortion relaxation layer 18A of the third active layer 18 is 700 to 800° C., and the growth temperature of the quantum well structural layer 18B is preferably 600 to 800° C. In this range, the distortion of the quantum well structural layer 18B can be effectively relaxed. When the wavelength corresponding to the band edge energy of the well layer of the distortion relaxation layer 18A is equal to the light emission wavelength of the second active layer 16, the growth temperature of the distortion relaxation layer 18A may be allowed to grow at the same growth temperature as the second active layer 16.

The distortion relaxation layer 18A is configured with the well layer and the barrier layer, but the well layer and the barrier layer may be formed at the same temperature, or the temperature may be different in the above temperature range. When the temperature is different. it is preferable to lower the growth temperature of the well layer than the growth temperature of the barrier layer. The quantum well structural layer 18B is also configured with a well layer and a barrier layer, but is also the same. Further, it is preferable that the growth temperature of the quantum well structural layer 18B is lower than the growth temperature of the second active layer 16.

The growth temperature of the protective layer 19 is preferably 500 to 950° C. This is to suppress heat damage to the first active layer 14, the second active layer 16, and the third active layer 18. In order to improve crystalline quality of the protective layer 19, higher growth temperature is preferable, more preferably 600 to 900° C., and still more preferably 700 to 900° C.

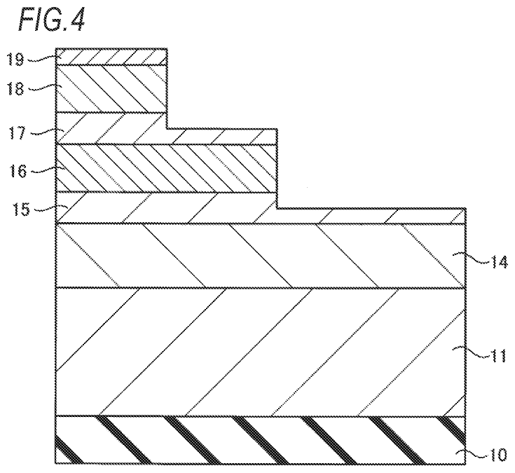

Next, a partial area on the protective layer 19 surface is dry etched until the partial area on the protective layer 19 surface reaches the second intermediate layer 17 to form the third groove 32, and is dry etched the partial area on the protective layer 19 surface reaches the first intermediate layer 15 to form the second groove 31 (refer to FIG. 4). The third groove 32 and the second groove 31 are preferably etched to the middle thickness of the second intermediate layer 17 and the first intermediate layer 15.

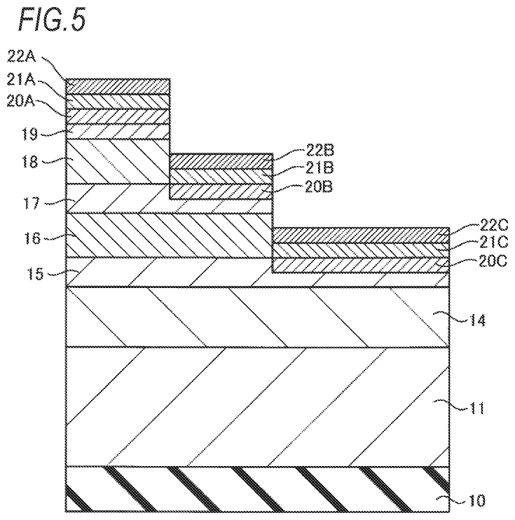

Next, the re-growth layers 20A to 20C, the electron blocking layers 21A to 21C, and the p-layers 22A to 22C are formed in order on the protective layer 19, the second intermediate layer 17 exposed by the third groove 32, and the first intermediate layer 15 exposed by the second groove 31 (refer to FIG. 5). The growth temperature of the re-growth layer 20A to 20C is the same as the protective layer 19. The growth temperature of the electron blocking layers 21A to 21C is preferably 750 to 1000° C. This is to suppress heat damage to the first active layer 14, the second active layer 16, and the third active layer 18. The growth temperature is more preferably, 750 to 950° C., and still more preferably 800 to 900° C. The growth temperature of the p-layers 22A to 22C is preferably 650 to 1000° C. The growth temperature is more preferably 700 to 950° C., and still more preferably 750 to 900° C.

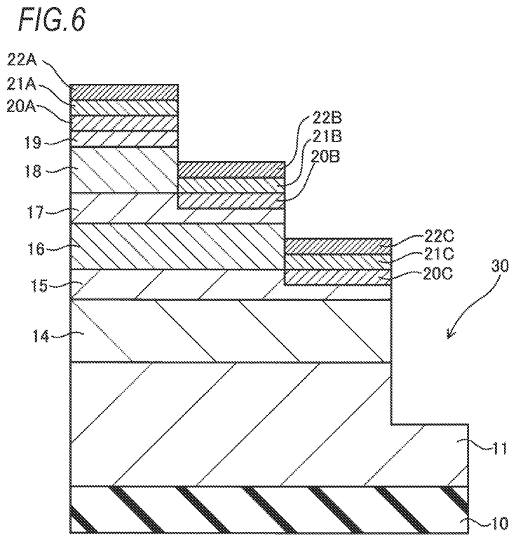

Next, the first groove 30 is formed until a partial area of the p-layer 22C surface reaches the n-layer 11 (refer to FIG. 6). Then, the n-electrode 23 is formed on the n-layer 11 exposed to the bottom of the first groove 30, and the p-electrodes 24A to 24C are formed on the p-layers 22A to 22C. As a result, the light emitting element in first embodiment is manufactured. (Modified Example of First Embodiment)

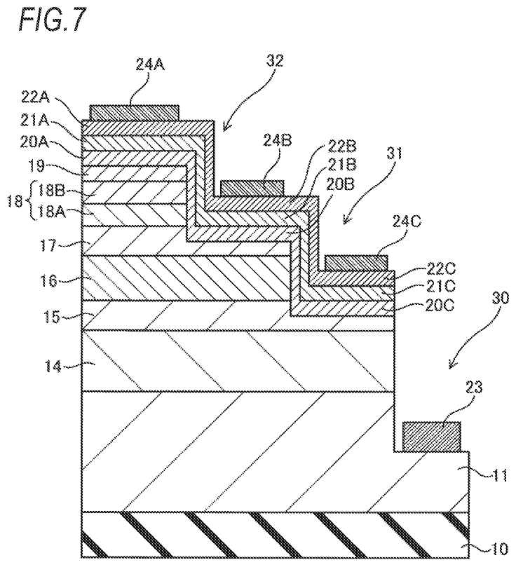

In the first embodiment, the re-growth layers 20A to 20C, the electron blocking layers 21A to 21C, and the p-layers 22A to 22C are separated, but may be in series (refer to FIG. 7). In this case, a re-growth layer, an electron blocking layer, and a p-layer are formed on the side of the third groove 32 and the side of the second groove 31, but has little influence on the operation of the element. The reason is as follows.

When the p-electrode 24A, the p-electrode 24B, and the p-electrode 24C are completely separated in space, the resistance of the p-layer connecting between the p-electrode 24A, the p-electrode 24B, and the p-electrode 24C is very high, a current does not almost flow. In addition, since the hole has a low movement, the hole does not spread in the horizontal direction from the area in contact with the electrode, and dominantly flows vertically at the pn junction directly under the electrode. For this reason, even when the re-growth layers 20A to 20C, the electron blocking layers 21A to 21C, and the p-layers 22A to 22C are in series, there is no influence on the operation of the element. In other words, when a current is allowed to flow to the p-electrode 24A, the current flows directly below the p-electrode 24A, and thus, the active layer directly below the p-electrode 24A emits light, and no current flows and no light is emitted in the active layer directly below the p-electrodes 24B and 24C.

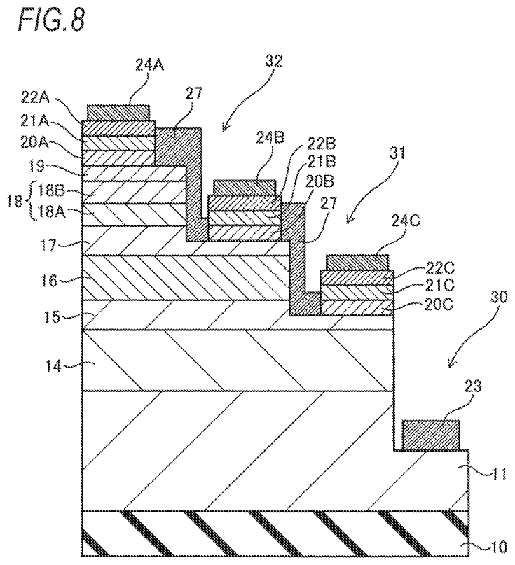

Further, as illustrated in FIG. 8, an insulating film 27 may be provided on the side of the third groove 32 or the side of the second groove 31. This insulating film 27 remains a mask for selecting and growing the re-growth layers 20A to 20C, the electron blocking layers 21A to 21C, and the p-layers 22A to 22C.

### Second Embodiment

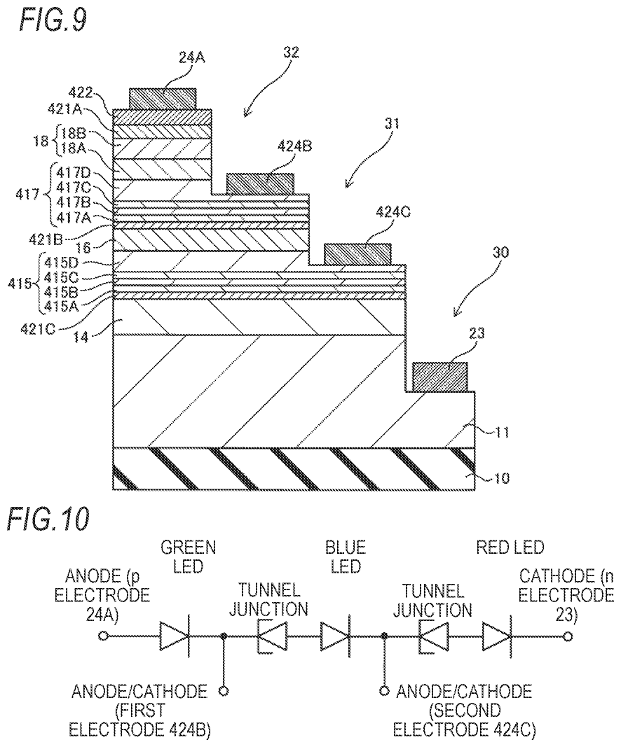

FIG. 9 is a diagram illustrating a configuration of a light emitting element in a second embodiment and is a cross-sectional view perpendicular to the main side of the substrate. As illustrated in FIG. 9, the light emitting element in the second embodiment is a change of the portion of the configuration of the light emitting element in the first embodiment as follows. The same configuration as the first embodiment is omitted in description with the same sign denoted.

As illustrated in FIG. 9, the first intermediate layer 15 and the second intermediate layer 17 are replaced, and a first intermediate layer 415 and a second intermediate layer 417 are provided. In addition, the protective layer 19, the re-growth layers 20A to 20C, the electron blocking layers 21A to 21C, and the p-layers 22A to 22C are omitted, an electron blocking layer 421A and a p-layer 422 are provided on the third active layer 18, and a p-electrode 24A is provided on the p-layer 422. In other words, there is no re-growth layer in the light emitting element in the second embodiment. Further, a first electrode 424B is provided on the first intermediate layer 415 exposed to the second groove 31 bottom, and a second electrode 424C is provided on the second intermediate layer 417 exposed to the third groove 32 bottom. Further, electron blocking layers 421B and 421C are inserted between the second active layer 16 and the second intermediate layer 17, and between the first active layer 14 and the first intermediate layer 15, respectively.

The electron blocking layer 421C is a p-type layer provided on the first active layer 14 and is located between the first active layer 14 and the first intermediate layer 15. The electron blocking layer 421C is the same as the electron blocking layer 21A to 21C, except for the continuous growth on the first active layer 14 instead of the re-growth layer.

The first intermediate layer 415 has a structure in which a first layer 415A (p-layer), a second layer 415B (p⁺-layer), a third layer 415C (n⁺-layer), and a fourth layer 415D (n-layer) are stacked in order from the first active layer 14 side, and the fourth layer 415D is exposed to the bottom of the second groove 31. The second layer 415B and the third layer 415C form a tunnel joint structure. As described above, the first intermediate layer 415 has a function of tunnel joint in addition to the same function as the first intermediate layer 15 in the first embodiment.

The first layer 415A is a semiconductor layer provided on the electron blocking layer 421C In order to efficiently emit the first active layer 14, it is preferable to sandwich the first active layer 14 with a p-type layer and an n-type layer, and the first layer 415A is provided as a p-type contact layer.

The material of the first layer 415A is the same as the first intermediate layer 15 in the first embodiment except for the impurities. That is, it may be a group III nitride semiconductor containing In, for example InGaN. The surfactant influence of In can suppress the roughness of the first intermediate layer 415 surface and improve the surface flatness. In addition, lattice distortion can be relaxed. The In composition of the first intermediate layer 415 may be set to be a band gap that does not absorb the light emitted from the first active layer 14, the second active layer 16, and the third active layer 18.

The preferred In composition of the first layer 415A is 10% or less, more preferably 5% or less, and still more preferably 2% or less. When the In composition is larger than 10%, the surface of the first intermediate layer 415 becomes rough. In is freely set when it is larger than 0%, and a dope level (a level that does not form a mixture) may be possible. For example, the In is GaN with an In concentration of 1×10¹⁴ cm⁻³ or more and 1×10²² cm⁻³ or less.

The first layer 415A is a p-type semiconductor doped with an Mg, which a p-type impurity. For example, the Mg concentration may be 1×10¹² to 10²⁰ cm⁻³, preferably 5×10¹² to 10²⁰ cm⁻³, and still more preferably 1×10¹⁹ to 1×10²⁰ cm⁻³. Non-doped may be suitable, but it is preferable that the semiconductor is doped with Mg as described above. The first layer 415A may use a polar dope that provides an inclination in the In composition in the thickness direction. In this case, undoped may be suitable. Further, the third layer 415C may be doped with Mg due to Mg diffusion from the electron blocking layer 421C, which is the lower layer of the first layer 415A. In this case, the Mg concentration of the electron blocking layer 421C is in the range of 1×10¹⁹ to 1×10²¹ cm⁻³.

It is preferable that the thickness of the first layer 415A is 10 to 300 nm. When the thickness is thicker than 300 nm, the surface of the first mid layer 415 may become rough. Further, when the thickness is thinner than 10 nm. it may not be possible to fully enhance the light emission efficiency of the first active layer 14. The thickness is more preferably 20 to 200 nm, and still more preferably 30 to 100 nm.

The second layer 415B is a semiconductor layer provided on the first layer 415A. A tunnel joint structure is formed by the stacked layer of the second layer 415B and the third layer 415C.

The material of the second layer 415B is the same except for the impurities of the first layer 415A. The In composition of the second layer 415B may be different from the In composition of the first layer 415A or the fourth layer 415D, and in that case, it is preferable to higher than the In composition of the first layer 415A or the fourth layer 415D. The tunnel probability can be increased by the tunnel joint structure. The preferred range of the In composition of the second layer 415B is the same as the first layer 415A.

The second layer 415B is a p-type semiconductor doped with Mg, which is a p-type impurity. The Mg concentration is 1×10²⁰ to 10²¹ cm⁻³. The Mg concentration of the second layer 415B is higher than the Mg concentration of the first layer 415A.

The thickness of the second layer 415B is 5 to 50 nm. In this range, the tunnel probability of the tunnel joint structure can be sufficiently enhanced. The thickness is more preferably 5 to 35 nm, and still more preferably 5 to 20 nm. Further, the thickness of the second layer 415B is preferably thinner than the first layer 415A.

The third layer 415C is a semiconductor layer provided on the second layer 415B. The tunnel joint structure is formed by stacking layers between the second layer 415B and the third layer 415C. The tunnel joint structure allows the current to flow from the n-type third layer 415C to the p-type second layer 415B by the tunnel effect, so that the holes are supplied to the first active layer 14.

The material of the third layer 415C is the same as the first layer 415A except for the impurities. The In composition of the third layer 415C may be different from the In composition of the first layer 415A or the fourth layer 415D, and in that case, it is preferable to higher than the In composition of the first layer 415A or the fourth layer 415D. The tunnel probability can be increased by the tunnel joint structure. Further, the In composition of the third layer 415C may be different from the In composition of the second layer 415B In that case, it is preferable that the In composition of the third layer 415C is lower than the In composition of the second layer 415B. The preferred range of the In composition of the third layer 415C is the same as the first layer 415A.

The third layer 415C is an n-type semiconductor doped with Si, which is an n-type impurities. The SI concentration is 1×10²⁰ to 1×10²¹ cm⁻³.

Near the joint interface between the second layer 415B and the third layer 415C, a layer co-doped with SI and Mg may exist intentionally or naturally Since Mg is easy to remain in the furnace due to the memory influence, Mg may be doped to the third layer 415C or the fourth layer 415D. However, the Mg concentration of the third layer 415C and the fourth layer 415D needs to be lower than each SI concentration.

The thickness of the third layer 415C is 1 to 30 nm. In this range, the tunnel probability of the tunnel joint structure can be sufficiently enhanced. The thickness is more preferably 2 to 25 nm, and still more preferably 5 to 20 nm. Further, the thickness of the third layer 415C is preferably thinner than the fourth layer 415D.

As described above, the second layer 415B and the third layer 415C, which form a tunnel joint structure, contain In, so that the band gap is small, and the tunnel probability is high. In addition, within the range of tunnel joint between the second layer 415B and the third layer 415C, a further layer may be provided between the second layer 415B and the third layer 415C. For example, a buffer layer may be provided to suppress Mg of the second layer 415B to be diffused to the third layer 415C.

The fourth layer 415D is a semiconductor layer provided on the third layer 415C In order to allow the second active layer 16 to efficiently emit light, it is preferable to sandwich the second active layer 16 with the p-type layer and the n-type layer, and the fourth layer 415D is provided as the n-type contact layer. Further, when the second groove 31 is formed, it is a layer that reaches the third layer 415C and does not expose.

The material of the fourth layer 415D is the same as the first intermediate layer 15 in the first embodiment except for the impurities. The In composition may be different from the first layer 415A.

The fourth layer 415D is an n-type semiconductor doped with Si, which is an n-type impurity. For example, the SI concentration may be 1×10¹⁷ to 10²⁰ cm⁻³, preferably 1×10¹⁸ to 10¹⁹ cm⁻³, and still more preferably 2×10¹⁸ to 8×10¹⁸ cm⁻³. The SI concentration of the third layer 415C is higher than the concentration of the impurities of the fourth layer 415D.

It is preferable that the thickness of the fourth layer 415D is 10 to 500 nm. When it is thicker than 500 nm, the surface of the first intermediate layer 415 may be caused to be rough. Further, when it is thinner than 10 nm, it may not be possible to fully enhance the light emission efficiency of the second active layer 16. Further, when forming the second groove 31, it may be difficult to control the depth of the second groove 31 in the fourth layer 415D. The thickness is more preferably 10 to 200 nm, and still more preferably 10 to 100 nm. The thickness of the fourth layer 415D may be different from the thickness of the first layer 415A.

The electron blocking layer 421B is a p-type layer provided on the second active layer 16 and is located between the second active layer 16 and the second intermediate layer 17. The electron blocking layer 421B is the same as the electron blocking layer 21A to 21C, except for the continuous growth on the second active layer 16 instead of the re-growth layer.

The second intermediate layer 417 has a structure in which a first layer 417A, a second layer 417B, a third layer 417C, and a fourth layer 417D are stacked in order from the second active layer 16 side, and the fourth layer 417D is exposed to the bottom of the third groove 32. The second layer 417B and the third layer 417C form a tunnel joint structure Thus, the second intermediate layer 417 has a tunnel joint function in addition to the same function as the second intermediate layer 17 in the first embodiment.

The first layer 417A, the second layer 417B, the third layer 417C, the fourth layer 417D are the same as the first layer 415A, the second layer 415B, the third layer 415C, the fourth layer 415D, respectively. The tunnel joint structure is formed by the stacked layer of the second layer 417B and the third layer 417C, and the current is allowed to flow from the n-type third layer 417C to the p-type second layer 417B, so that the current flows, and thus, the hole is allowed to be supplied to the second active layer 16.

Since all layers of the first intermediate layer 415 and the second intermediate layer 417 are configured with InGaN, the same influence is obtained as the first intermediate layer 15 and the second intermediate layer 17 in the first embodiment. In other words, the surface flatness can be improved, and the lattice distortion can be relaxed.

The average In composition of the first intermediate layer 415 and the average In composition of the second intermediate layer 417 may be different. It is preferable that the average In composition of the second intermediate layer 417 is higher than the average In composition of the first intermediate layer 415.

The electron blocking layer 421A is a p-type layer provided on the third active layer 18. The electron blocking layer 421A is the same as the electron blocking layers 21A to 21C, except for the continuous growth on the third active layer 18 instead of the re-growth layer.

The p-layer 422 is a layer provided on the electron blocking layer 421A The p-layer 422 is the same as the p-layer 22A, except for the continuous growth on the electron blocking layer 421A instead of the re-growth layer.

Instead of the p-layer 422, a tunnel joint structure such as a second layer 415B, a third layer 415C, or the second layer 417B and the third layer 417C may be used. In this case, the electrode can be used to use an n contact material, which is replaced with a p-electrode 24A, and can be used as the same material as the first electrode 424B and the second electrode 424C. For this reason, all electrodes can be formed in the same process.

The first electrode 424B is provided on the fourth layer 417D of the second intermediate layer 417, which is exposed to the bottom of the third groove 32. Further, the second electrode 424C is provided on the fourth layer 415D of the first intermediate layer 415 exposed to the bottom of the second groove 31. The first electrode 424B and the second electrode 424C also have anode and cathode electrodes. The first electrode 424B and the second electrode 424C may be an ohmic contact with n-type InGaN, for example, a Ti/Al. The same material as the n-electrode 23 may be used.

Various deformation described in the first embodiment can also be applied in the second embodiment.

Next, the operation of the light emitting element in the second embodiment is explained. In the light emitting element in the second embodiment, the green light can be emitted from the third active layer 18 by applying the voltage between the p-electrode 24A and the first electrode 424B Further, by applying a voltage between the first electrode 424B and the second electrode 424C, the blue light can be emitted from the second active layer 16. Further, by applying a voltage between the second electrode 424C and the n-electrode 23, the red light can be emitted from the first active layer 14.

In addition, two or more of blue, green, and red can be emitted at the same time. Specifically, the voltage is applied as follows. To emit all of blue, green, and red, the voltage is applied between the p-electrode 24A and the n-electrode 23. When the green and red are emitted simultaneously, the voltage is applied between the p-electrode 24A, the first electrode 424B, and between the second electrode 424C and the n-electrode 23. When the blue and green are emitted at the same time, the voltage is applied between the p-electrode 24A and the second electrode 424C. When the blue and red are emitted at the same time, the voltage is applied to the first electrode 424B and the n-electrode 23.

As described above, in the light emitting element in the second embodiment, blue, green, and red light emission can be controlled by selecting electrode to which the voltage is applied, and can be used as one pixel of a display.

FIG. 10 illustrates an equivalent circuit of the light emitting element in the second embodiment. The light emitting element in the second embodiment is equivalent to the configuration where the red LED, the first tunnel junction (reverse order tunnel diode), the blue LED, the second tunnel junction, and the green LED are cascades connected and the electrodes are extracted from the connection between the red LED and the first tunnel junction and connection and the connection between the blue LED and the second tunnel junction. Similarly to the light emitting elements in first embodiment, the light emitting element in the second embodiment also has a structure in which blue, green, and red LEDs are formed in one element, and full-color light emission can be realized with one element.

Next, the processes of manufacturing the light emitting element in the second embodiment are explained.

First, the substrate 10 is prepared and the heat treatment is performed similarly to the first embodiment. After that, on the substrate 10, the buffer layer, the n-layer 11, the ESD layer 12, the underlying layer 13, the first active layer 14, the electron blocking layer 421C, the first intermediate layer 415, the second active layer 16, the electron blocking layer 421B, the second intermediate layer 417, the third active layer 18, the electron blocking layer 421A, and the p-layer 422 are formed in order by the MOCVD method.

Here, the growth temperature of the first intermediate layer 415 and the second intermediate layer 417 is the same as the first intermediate layer 15 and the second intermediate layer 17 in the first embodiment. It is preferable that the growth temperature of the second intermediate layer 417 is lower than the growth temperature of the first intermediate layer 415. This is because the third active layer 18 of the green light emission is more susceptible to heat damage than the second active layer 16 of the blue light emission, which increases the influence of distortion at the interface.

Further, in the formation of the first intermediate layer 415, the growth temperature of the second layer 415B and the third layer 415C is preferably lower than the growth temperature of the first layer 415A and the fourth layer 415D. This is to increase crystallinity and enhance the tunnel effect in tunnel joint. Further, in the formation of the second intermediate layer 417, the growth temperature of the second layer 417B and the third layer 417C is preferably lower than the growth temperature of the first layer 417A and the fourth layer 417D.

Next, a partial area of the p-layer 422 surface is dry etched until the etching reaches the fourth layer 417D of the second intermediate layer 417 to form the third groove 32, dry etching is performed until the etching reaches the fourth layer 415D of the first intermediate layer 415 to form the second groove 31, and dry etching is performed until the etching reaches the n-layer 11 to form the first groove 30.

Next, the n-electrode 23 is formed on the n-layer 11 exposed to the bottom of the first groove 30, the p-electrode 24A is formed on the p-layer 422, the first electrode 424B is formed on the bottom of the third groove 32, and the second electrode 424C is formed on the bottom of the second groove 31. When the same material as the n-electrode 23 is used for the first electrode 424B and the second electrode 424C, the electrodes can be formed by using the same process as the n-electrode 23 at the same time. As a result, a light emitting element in the second embodiment is manufactured.

As described above, the light emitting element in the second embodiment has a tunnel joint structure in the first intermediate layer 415 and the second intermediate layer 417, which eliminates the need to provide an electron blocking layer or a p-layer re-growth layer. Since etching damage, impurity contamination due to air exposure, and beat damage caused by re-growth occur at the re-growth interface, when there is a re-growth interface between the pn, the device characteristics may worsen. However, since the light emitting element in the second embodiment has no re-growth layer and there is no re-growth interface between the pn, there is no such problem.

Furthermore, in the second embodiment, the EU-doped GaN is used as a red light emitting material similarly to the first embodiment. For this reason. the light emission efficiency of the red light can be improved.

What is claimed is:

1. A light emitting element made of a face-up type group III nitride semiconductor, comprising:
a substrate;
an n-layer provided on the substrate and made of an n-type group III nitride semiconductor;
a first active layer provided on the n-layer, using an EU-doped group III nitride semiconductor as a light emitting material, and emitting red light;
a first intermediate layer provided on the first active layer and formed by stacking a first undoped layer made of a group III nitride semiconductor containing an undoped In and a first n-type layer made of a group III nitride semiconductor containing an n-type In in order; and
a second active layer provided on the first intermediate layer, using a group III nitride semiconductor containing In as a light emitting material, and emitting light with a wavelength shorter than that of the first active layer,
wherein, in the first intermediate layer, an In composition is set so that a band gap does not absorb the light emitted from the first active layer.

2. The light emitting element according to claim 1, wherein a thickness of the first intermediate layer is 150 nm or less, and a thickness of the first undoped layer and a thickness of the first n-type layer are 10 μm or more.

3. The light emitting element according to claim 1, further comprising:
a second intermediate layer provided on the second active layer and formed by stacking a second undoped layer made of the group III nitride semiconductor containing the undoped In and a second n-type layer made of the group III nitride semiconductor containing the n-type In in order; and
a third active layer provided on the second intermediate layer, using a group III nitride semiconductor containing In as a light emitting material, and emitting with a wavelength shorter than that of the first active layer and different from that of the second active layer,
wherein one active layer of the second active layer and the third active layer is of blue light emission, and the other active layer is of green light emission,
wherein, in the first intermediate layer and the second intermediate layer, the In composition is set so that the band gap does not absorb the light emitted from the first active layer and the second active layer,
wherein the green light emission of the second active layer and the third active layer corresponds to a structure in which a distortion relaxation layer which is a quantum well structure and a thickness of a well layer is adjusted so as not to emit light and a light emission layer which is a quantum well structure and emits light are stacked in order, and
wherein a wavelength corresponding to band edge energy of the well layer of the distortion relaxation layer is set to be shorter than a light emission wavelength of the light emission layer.

4. A light emitting element made of a face-up type group III nitride semiconductor, comprising:
a substrate;
an n-layer provided on the substrate and made of an n-type group III nitride semiconductor;
a first active layer provided on the n-layer, using an EU-doped group III nitride semiconductor as a light emitting material, and emitting red light;
a first intermediate layer provided on the first active layer, made of a group III nitride semiconductor containing In, and having a structure formed by stacking a p-type first p-type layer, a p-type first p⁺-layer, an n-type first n⁺-layer, and an n-type first n-layer in order from the first active layer, and
a second active layer provided on the first intermediate layer, using a group III nitride semiconductor containing In as a light emitting material, and emitting light with a wavelength shorter than that of the first active layer,
wherein the p-type impurity concentration of the first p⁺-layer is higher than the p-type impurity concentration of the first p-layer, and the n-type impurity concentration of the first n⁺-layer is higher than the n-type impurity concentration of the first n-layer, and the first p⁺-layer and the first n⁺-layer form a tunnel joint structure, and
wherein, in the first intermediate layer, an In composition is set so that a band gap does not absorb the light emitted from the first active layer.

5. The light emitting element according to claim 4, wherein an In composition of the first p⁺-layer and the first n⁺-layer is higher than the In composition of the first p-layer and the first n-layer.

6. The light emitting element according to claim 4, wherein the In composition of the first p⁺-layer is higher than the In composition of the first n⁺-layer.

7. The light emitting element according to claim 4, further comprising:
a second intermediate layer provided on the second active layer and having a structure in which a p-type second p-layer, a p-type second p⁺-layer, an n-type second n⁺-layer, and an n-type second n-layer are stacked in order from the second active layer; and
a third active layer provided on the second intermediate layer and using a group III nitride semiconductor containing In as a light emitting material and emitting light with a wavelength shorter than the first active layer and with a different wavelength from the second active layer,
wherein the p-type impurity concentration of the second p⁺-layer is higher than the p-type impurity concentration of the second p-layer, the n-type impurity concentration of the second n⁺-layer is higher than the n-type impurity concentration of the second n-layer, and the second p⁺-layer and the second n⁺-layer form a tunnel joint structure,
wherein, in the first intermediate layer and the second intermediate layer, an In composition is set so that a band gap does not absorb the light emitted from the first active layer and the second active layer,
wherein one active layer of the second active layer and the third active layer is of blue light emission, and the other active layer is of green light emission,
wherein the green light emission of the second active layer and the third active layer corresponds to a structure in which a distortion relaxation layer which is a quantum well structure and a thickness of a well layer is adjusted so as not to emit light and a light emission layer which is a quantum well structure and emits light are stacked in order, and
wherein a wavelength corresponding to band edge energy of the well layer of the distortion relaxation layer is set to be shorter than a light emission wavelength of the light emission layer.

8. The light emitting element according to claim 3, wherein the wavelength corresponding to the band edge energy of the well layer of the distortion relaxation layer is set to be equal to the light emission wavelength of the blue light emission of the second active layer and the third active layer.

9. The light emitting element according to claim 7, wherein the wavelength corresponding to the band edge energy of the well layer of the distortion relaxation layer is set to be equal to the light emission wavelength of the blue light emission of the second active layer and the third active layer.

10. The light emitting element according to claim 3, wherein a difference between the light emission wavelength of the light emission layer and the wavelength corresponding to the band edge energy of the well layer of the distortion relaxation layer is set to be in the range of 40 nm and more or 100 nm or less.

11. The light emitting element according to claim 7, wherein a difference between the light emission wavelength of the light emission layer and the wavelength corresponding to the band edge energy of the well layer of the distortion relaxation layer is set to be in the range of 40 nm and more or 100 nm or less.
